(19) United States
(12) Patent Application Publication
(10) Pub. No.: US 2010/0090189 A1
(43) Pub. Date: Apr. 15, 2010

(54) Nanoscale electrical device

(76) Inventor: Semyon D. Savransky, Newark, CA (US)

Correspondence Address: Semyon D. Savransky, 6015 PepperTree Court, Newark, CA, 94560, US

(21) Appl. No.: 12/584,844

(22) Filed: Sep. 14, 2009

Related U.S. Application Data
(60) Provisional application No. 61/096,866, filed on Sep. 15, 2008.

(51) Int. Cl. H01L 47/00; H01L 29/18; H01L 29/04

(52) U.S. Cl. 257/2; 257/42; 257/52; 257/E47.001; 257/E29.087; 257/E29.003

(57) ABSTRACT

A device consists a disordered relaxation insulator or/and a polyamorphous solid between two or more electrodes. Invented devices can perform passive, logic and memory functions in an electronic integrated circuit.

### CROSS REFERENCE TO RELATED APPLICATIONS

Benefit of U.S. Provisional Application No. 61/096,866 (EFS ID: 3939160) filed Sep. 15, 4508, is claimed. The application is incorporated herein by reference.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable

### STATEMENT REGARDING FEDERALLY SPONSORED RESEARCH OR DEVELOPMENT

Not Applicable.

### BACKGROUND OF THE INVENTION

1. Field of the Invention

The instant invention relates to a novel family of semiconductor devices that can carry both logical and memory functions for fully general computing utilizing a single active disordered material. More specifically the present invention relates to electronic devices whose functional length scales are measured in nanometers and to the devices which can be manufactured by methods known in semiconductor industry.

The present invention relates to nanoscale electronic devices that have several volatile and non-volatile states. These devices can be used in logic or/and memory electronic integrated circuits (IC) such as volatile and nonvolatile electrical memories, microprocessors, microcontrollers, programmable arrays.

2. Description of the Related Prior Art and Technical Problems

Conventional electronic integrated circuits (IC) consist of several different semiconductor devices such as transistors, resistors and capacitors. These IC components broadly fall into three distinct categories, namely, passive components, active components and configurable components.

a) The passive components such as resistors and capacitors have relatively constant electrical values.

b) The electrical values of active components such as transistors are designed to change each time when a voltage or current is applied to control electrodes. The active components of IC have three major functions: to perform logical operation (such as AND, OR, and XOR) with discrete electrical signals, to store (temporary or permanently) data (i.e., coded electrical signals), and to change discrete or continuous electrical signals (e.g., amplify).

c) The configurable components do not have pre-determined electrical values and suppose to change electrical values associated with them by special request from other IC components or IC users (fuses, programmable logical arrays, reconfigurable cells, antifuses, etc.), with environment conditions (sensors of temperature, pressure, radiation, etc.) or with time (chronological cells).

Different types of passive, active and configurable semiconductor devices often co-exist in the same IC. These devices are made during different steps in IC production and therefore increase IC cost. Majority of IC components are often produced directly on silicon wafers. Therefore, the silicon real estate is quite expensive. The major trend of semiconductor industry is to decrease the area for each component of IC and build more and more semiconductor devices on the same silicon real estate. Unfortunately standard semiconductor technology will face multiple physical barriers after shrinking current devices below about 16 nm, therefore different alternative approaches are widely studied.

Recently a great amount of attention has been given to other alternative technologies based on new materials, for example carbon nanotube devices, polymer switches, etc. Unfortunately there is still a great number of problems associated with these approaches like extreme difficulties in manufacturing, non-optimal electrical characteristics and performances, incompatibility with CMOS technology, etc. Such disadvantages prevent the widespread application of these ideas.

Accordingly in view of the various problems associated with conventional and new semiconductor devices described above, it is highly desirable to have a device that is able to provide most of functions of passive, active and configurable components of IC. Such device should be inherently simple and inexpensive to produce, and should be used as most passive and active components of IC. Such device should not require silicon real estate, and should have small (preferable 1-15 nm) size, and should be compatible with CMOS technology. Furthermore, such device should meet the requirements of the new generations of equipment and gadget that will use advanced IC (e.g., robots, portable HDTV players, personal digital assistant) by operating under a low power while providing high density and poly-functionality with low manufacturing cost.

While material requirements for such electronic devices are clearly diverse, they have certain characteristics in common. Parameters that are necessarily tailored to specific device needs include resistivity, number of mobile carriers, number of donor and acceptor impurities and distribution, junction configuration, traps—their nature and distribution, junction profile, etc. Presently semiconductor materials (such as Si, Ge, SiGe, InSb, GaAs) in which carrier lifetime is greater than dielectric relaxation time are used in IC. In these materials the space charge associated with injected minority characters is virtually instantaneously neutralized by the equal and opposite charge produced by a perturbation in distribution of mobile majority carriers.

Most semiconductor devices utilize minor carriers related to doping of the material. Active material in most of electronic devices has crystalline or poly-crystalline atomic structure and can be characterized as a diffusion lifetime semiconductor or insulator. These devices cannot scale down below about 10 nm.

Some semiconductor devices are based on disordered semiconductors such as amorphous silicon or phase-change alloys disclosed in U.S. Pat. No. 5,166,758 issued Nov. 24, 1992 or threshold switching alloys disclosed in U.S. Pat. No. 3,271,591 issued Sep. 6, 1966.

It has been shown [1A] that nanometer scale latches with hysteretic resistors characteristics (e.g., switches) can product logic functions. Unfortunately the materials for such latches logic are unknown [1A, 1B]. On another hand, chalcogenide switches disclosed in U.S. Pat. No. 3,271,591 issued Sep. 6, 1966 might be suitable for such latches [10]. U.S. Pat. No. 5,543,737 (reference 10) proposes two or more chalcogenide switches with different threshold voltage Vth that can work as such latches. It is known in the art that threshold switching voltage Vth is a function of chalcogenide alloy thickness or Vth can be changes with chalcogenide alloy chemical composition. It is not desired for mass production to have different chalcogenide alloy chemical compositions in the same IC or to use switches with different thickness of a chalcogenide alloy.

The threshold switch is a device which, after being driven from its non-conductive state with resistivity in the range of about 10.sup.4 to about 10.sup.7 ohm centimeters into its conductive state with resistivity in the range of from 160 to about 10.sup.-.sup.6 ohm, centimeters by a voltage in excess of threshold voltage value, remains in its conductive state until the current flow drops below a given holding current value, as explained in the aforesaid U.S. Pat. No. 3,271,591.

The phase-change memory is a device which, after being driven from its non-conductive state with resistivity in the range of about 10.sup.2 to about 10.sup.5 ohm centimeters into its conductive state with resistivity in the range of from 10 to about 10.sup.-.sup.2 ohm centimeters by a voltage in excess of threshold voltage value, remains in its conductive state even after all sources of energy are removed from a device, and is resettable back to its relatively non-conductive state by application of a reset pulse, as explained in the aforesaid U.S. Pat. No. 5,166,758. The current pulse that sets a memory material in conductive crystalline state is generally a pulse of about 300 nanosecond duration. The pulse that resets a memory material in non-conductive amorphous state is a very short current pulse lasting generally less than about 10 nanoseconds in duration. These memory materials can be changed reversibly between two structural states (amorphous and crystalline).

The phase-change alloys are generally chalcogenide (usually Te) or pnictide (usually Sb) bases composition that can be switched between single amorphous and single or multiple crystalline phases. An example of composition is 52% tellurium, 24% antimony and 24% germanium. The threshold switching alloys are generally chalcogenide glasses, an example of composition is 40% tellurium, 35% arsenic, 18% silicon, 6.75% germanium, and 0.25% indium.

Such switching and memory devices are mostly based on the use of semiconductor material in single amorphous configuration. Non-volatile memory cells based on disordered semiconductors (for example, phase-change memory) require selector devices such as transistor or diode in order to avoid sneak path for leakage current in memory array. Selector free phase-change memory [2] is based on devices with different programmable volume of phase-change alloys in single amorphous state. Relatively small impedance of memory cells based on Ge—Sb—Te phase-change alloy and small (less than 0.5V) difference in threshold switching voltages in memory cells programmed to different ratio of volumes of amorphous and crystalline phase-change alloy limit memory array cost ineffective to 8 by 8 cell size or even smaller [3]. A big memory selector-free array can be used in cost effective memory, including non-volatile and three dimension memories. A growing demand for cheap high density, high performance memories for information storage and retrieval dictates search of new memories [4-7].

Therefore the strong demand for new passive and active (for logic and memory functions) devices scalable beyond 15 nm exists in electronic industry.

### SUMMARY OF THE INVENTION

A new class of devices for passive, configurable, and active (logic or/and memory) applications is described. These devices utilize a disordered material that has low impedance state and two or more high impedance states with different disordered atomic configurations in some of which dielectric relaxation time, defined as the product of resistivity and the real component of permittivity, exceeds diffusion length lifetime. The generic device has two electrodes and the disordered material without p-n junction although variations may incorporate p-n junctions and/or more electrodes.

By the term “disordered” is meant a material without long range order, although it may contain isolated domains having an ordered structure in a primarily disordered matrix.

I use the term “polyamorphous” [8] for disordered material with two or more different disordered atomic configurations.

I define term “dielectric relaxation time” as the product of resistivity and the real component of the dielectric constant.

I use the terms “relaxation insulator” and “relaxation semiconductor” [9] for a disordered material with high impedance and a dielectric relaxation time exceeding a diffusion lifetime in two times or more.

Semiconductor or insulator materials with electron type of conductivity can be classified depending on the response of the material to majority carrier injection, as a relaxation type and lifetime type. The injection of majority carriers leads to majority carrier depletion in relaxation type materials in which the Debye length is greater than the diffusion length. The injection of majority carriers leads to majority carrier augmentation in lifetime type materials in which the Debye length is smaller than the diffusion length.

The invented device is based on polyamorphous material (atomic signature of a disordered material) or on relaxation insulator (electrical signature of a disordered material). The invented device may operate as constant or variable passive component (resistor or/and capacitor), as switch (or latch) for logic IC, as recording media for memory IC, or as a current or voltage control device.

The electrical characteristics of invented device can be tuned by application of electromagnetic or other forms of energy to the disordered material. In another embodiment different high impedance states have different threshold switching voltages. In still another embodiment different high impedance states can be obtained by application of different electrical pulses between the electrodes of invented device.

### BRIEF DESCRIPTION OF THE DRAWING

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1 shows exemplary device in a plan view in accordance with this invention.

FIG. 2 shows a sketch of potential energy versus configuration coordinate for a solid material.

FIG. 3 shows forward I-V curves plotted from current-voltage measurements of device in accordance with the invention programmed to two high impedance states.

FIG. 4 shows exemplary programming of device in accordance with the invention to two levels of threshold switching voltage.

FIG. 5 shows dependence of threshold voltages from programming cycle in the invented device programmed to two different high impedance polyamorphous states of relaxation semiconductor.

FIG. 6 shows an exemplary crossbar array in a perspective view that consists of the invented devices.

### DETAILED DESCRIPTION

Tentative explanations are given for some of the observed phenomena in invented device. Such theoretical considerations are not to be construed as limiting the appended claims that are set forth in terms of measurable device parameters. Postulated mechanisms set forth in this section as well as that preceding are intended to aid the practitioner to make specific utilization of device characteristics.

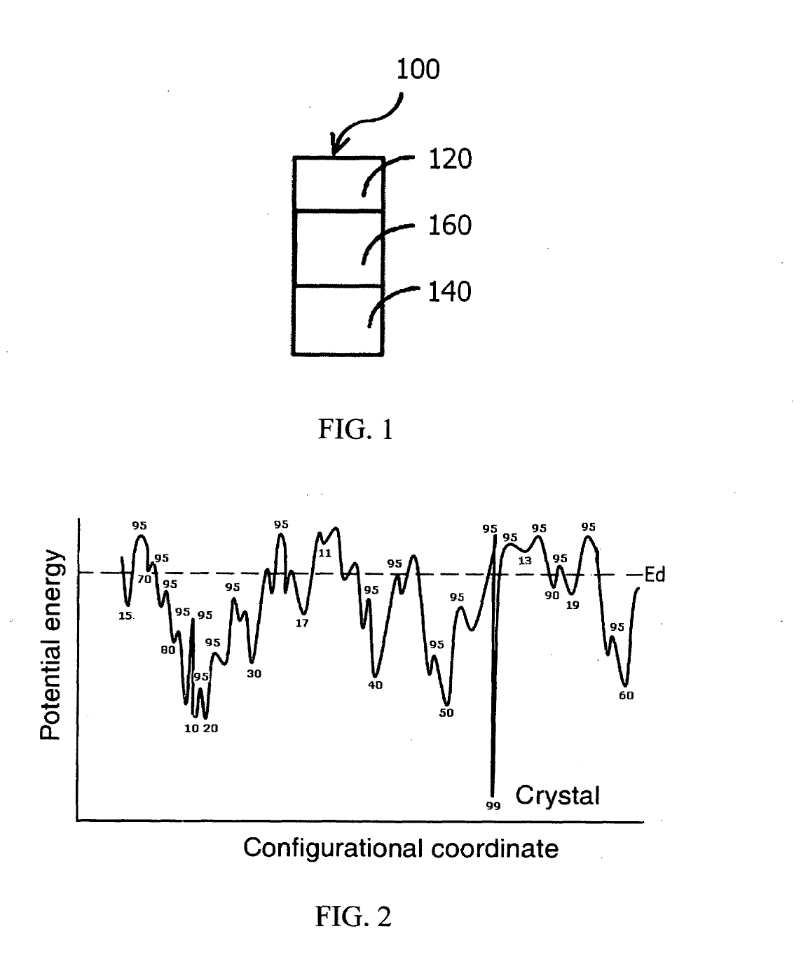

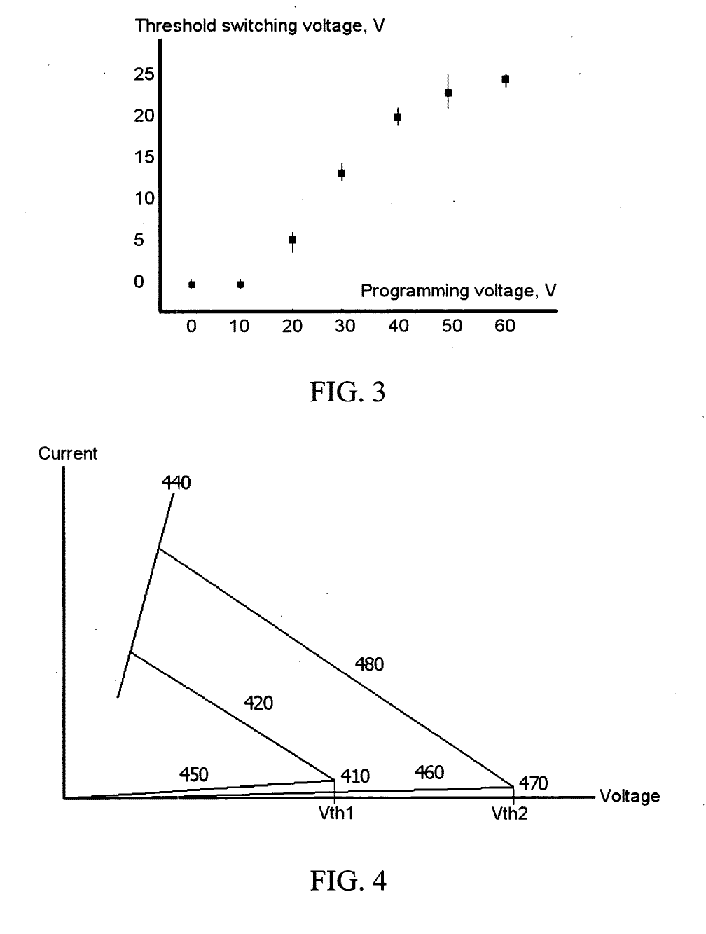

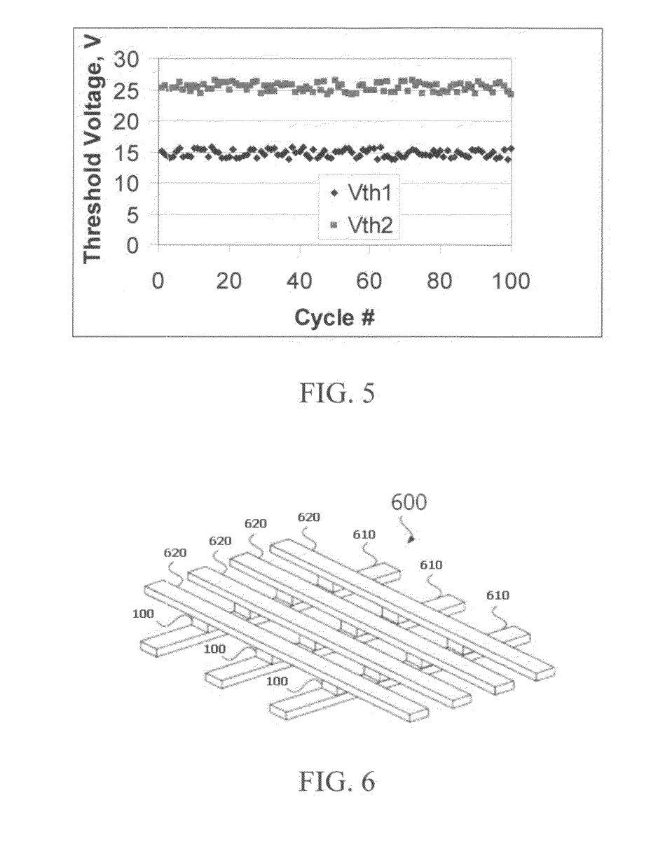

The description in terms of the experimental results obtained with invented device shown in FIG. 1 which yielded the data plotted in FIG. 3 and FIG. 5.

FIG. 1 shows the invented device 100 that compromises a disordered material 160 between a first electrode 120 and a second electrode 140. The methods of manufacturing of the invented device 100 consist of deposition and pattering of the first electrode 140, then deposition and pattering of the disordered material 160 and finally deposition and pattering of the second electrode 120. In some embodiments CVD or/and PVD are used for the deposition. In some embodiments photolithography of the electrodes 120 and 140 and the disordered material 160 followed by etching are used for the pattering. In some embodiments the disordered material 160 is deposited as thin film in polycrystalline or amorphous form.

The electrodes 120 and 140 are made from carbon (C) or metal such as Mo, Pt, Ti, Ta, Ni, Cr and their combinations in some embodiments with other metals or non-metals such as Si, Ge, N, O, F in the chemical composition or from cermet such as TiAlN, TiSiN or superconductor such as Hg12Tl3Ba30Ca30Cu45O125, YBa2Cu3O7.

The disorder material 160 is usually inorganic, although some organic materials with at least one carbon-hydrogen (C—H) bond or/and at least one carbon-oxygen (C—O) bond have polyamorphous atomic structure or/and can be relaxation insulators.

Chemical composition of the inorganic disordered material 160 compromises at least one chalcogen element (tellurium Te, selenium Se, sulfur S, oxygen O) or at least one element of nitrogen group including nitrogen (N), phosphorus (P), arsenic (As), antimony (Sb), bismuth (Bi) or at least one element of boron group including boron (B), aluminum (Al), gallium (Ga), indium (In), thallium (Tl) or at least one metalloids such as silicon (Si) or germanium (Ge) or carbon (C) and their combinations in some embodiments.

The inorganic disordered material 160 compromises in some embodiments of at least one of oxides WO3 or PbO or V2O5 or CuO or Fe2O3 or Ag2O or MgO or CaO or SrO or BaO or CdO or ZnO or CeO2 or Pr2O3 or Nd2O3 or TeO or Sb2O3 or TiO2. The preferable embodiments of the inorganic disordered material 160 include the following alloys: Ga—Sb—Te, In—Sb—Te, Al—Sb—Te, Ga—As—Sb—Te, In—As—Sb—Te, Al—Sb—As—Te, Ga—Sb—Te—Se, In—Sb—Te—Se, Al—Sb—Te—Se, In—Sb—Se—TeO2-V2O5, TiO2-Sb—Te.

In one embodiment the first 140 and second 120 electrodes form crossbar array with the disordered material 160 in cross-points of this array (see also FIG. 6).

Because the device 100 does not have a p-n junction its current (I)−voltage (V) characteristic is symmetrical. In some embodiments the device 100 has the electrodes 120 and 140 from different materials and its I-V characteristic is asymmetrical due to contact barriers between these electrodes and disordered material 160.

In some embodiments the distance between the electrodes 120 and 140 is between 1 nm and 1 mm, preferably 10 nm and the maximum area of the disordered material 160 or the electrodes 120 and 140 is smaller than 45000 square nm, preferably smaller than 450 square nm.

A sketch of potential energy versus configuration coordinate for a solid material is shown in FIG. 2. Several energy minimums (wells) 10-90 for a disordered polyamorphous material are shown together with energy barriers 95. The single and deepest well 99 corresponds to the crystalline form of the material. Each other energy well corresponds to the unique atomic configuration of the disordered material.

Transitions between these energy wells can occur in the disordered material 160 due to application of an electrical signal between first and second electrically conductive electrodes 120 and 140. Probability to have atomic configuration that corresponds to the energy wells 10, 20, 30, 40, 50, 60 is higher than for the energy wells 70, 80 and 90 for the disordered material 160 because energy barriers 95 around these wells 10, 20, 30, 40, 50, 60 are higher to compare with the barriers 95 around wells 70, 80 and 90. The existence of two or more deep energy wells like 10, 20, 30, 40, 50, 60 allows the disordered material 160 to exist in various metastable polyamorphous configurations.

Each energy well (e.g., 11 or 50 or 99) shown in FIG. 2 corresponds to specific electrical and other properties of the disordered polyamorphous material 160. Therefore the polyamorphous material 160 has two or more metastable energy wells that correspond to high impedances of the device 100 in non-volatile states. The disordered material 160 in these states has S-type of I-V characteristics with the distinguished threshold switching voltage Vth. Possible values of Vth of the device 100 are between 0.1V and 160V and the difference between threshold voltages in two of high impedances states of the device 100 is 0.3V and above, preferably above 2V and below 50V.

In some embodiments the polyamorphous material 160 is settled in one of energy wells (e.g., 20 or 40 or 60) in the high impedance state with potential energy significantly smaller than a demarcation energy Ed. In some embodiments the polyamorphous material 160 is settled in one of metastable energy wells (e.g. 11 or 19) in the low impedance state with potential energy near demarcation energy Ed. In another embodiment the crystalline material 160 is settled in stable in the energy well 99 in the low impedance state.

In some embodiments the device 100 has resistance at least 10 MOhm, (preferably above 1 GOhm) in the high impedance state. In other embodiments the device 100 has resistance at most 30 kOhm (preferably below 1 Ohm) in the low impedance state.

In some embodiments the states with low and high impedances are volatile and in other embodiments the states with low and high impedances are non-volatile.

An electrical property of device 100 can be altered between various high impedance states or between high and low impedance states upon application of an electrical signal (such as electrical potential difference between first 120 and second 140 electrodes or electrical current through disordered material 160). The state of device 100 can be detected upon application of an electrical signal. The electrical signal is a finite time pulse such as rectangular pulses or triangular pulses or free-shape pulses with uniform or non-uniform amplitudes and/or durations in some embodiments.

In some embodiments the disordered material 160 has strong interaction between free charge carriers (electrons or holes) or charge carriers localized at traps in forbidden gap of the material 160 and atomic network in one or more of its polyamorphous configurations.

In another embodiment the interaction between charge carriers and atomic configuration excitations (e.g., phonons) in material 160 leads to self-trapping of the charge carriers (e.g. polarons creation). In still another embodiment this interaction is stronger than the Coulomb repulsion between similar charge carriers (e.g., between 2 electrons), and therefore centers with negative Hubbard correlation energy (−U centers) exist in the material 160. These −U centers with preferably concentration above 10̂17 cm³ pin the Fermi level near middle of forbidden gap of the material 160 and cause it high impedance.

In some embodiments electromagnetic or mechanical (for example pressure) or chemical (for example exposure of the material 160 to a gas environment) or another form of energy is used to alter the properties of the material 160.

FIG. 3 shows programming of invented device 100 to different threshold switching voltages Vth due to application of an electrical signal (programming voltage in this case). Shown plurality of the voltages Vth or different impedance states is the result of the transitions between different energy wells 10-90 in the polyamorphous material 160.

Current-voltage (I-V) characteristics of the device 100 without any p-n junction are symmetric with respect to the polarity of the applied voltage. For convenience, I consider the first quadrant of the I-V plot of FIG. 4 (the portion in which current and voltage are both positive) in the brief discussion of device 100 behavior that follows. Analogous device 100 behavior occurs in the third quadrant of the I-V plot shown in FIG. 4. Provided one is cognizant of the negative polarity of the I-V curve in the third quadrant, the behavior and current characteristics in the third quadrant is analogous to that described hereinabove for the first quadrant. For example, applied voltages having a magnitude greater than the magnitude of the minimal negative threshold voltage in the third quadrant induce a switching from high impedance branch to the low impedance branch.

FIG. 4 shows I-V characteristics of a device 100 programmed to low threshold switching voltage 410 (Vth1) and to high threshold switching voltage 470 (Vth2). Two high impedance states of material 160 are marked as 450 and 460. An electric current is passing through the material 160 when a electric voltage applied between the electrodes 120 and 140. This current increases only slightly upon increasing the voltage applied across the material 160 in any of high impedance states 450 and 460. Low impedance state of material 160 is marked as 440. A current passing through a material 160 increases significantly upon increasing the voltage applied across the material 160 in the state 440. Transitions between a high impedance and the low impedance states occur along the line 420 or the line 480.

I initially consider the disordered material 160 with threshold voltage Vth1 when no voltage difference is present between the electrodes 120 and 140 and when no current flows through the device 100. This condition corresponds to the origin of the I-V plot shown in FIG. 4. The material 160 remains in a high state 450 when the applied voltage is increased to a threshold voltage Vth (see FIG. 4). A small slope of the I-V curve for applied voltages between zero 0 and Vth1 indicates that the disordered material 160 has high electrical impedance. When the applied voltage equals or exceeds the threshold voltage 410, the disordered material 160 switches to the low impedance state 440. The switching event occurs almost instantaneously (characteristic time is below 160 picoseconds) and is depicted by the load line 420 in FIG. 4 from the threshold current I@Vth1 to some value of current in the low impedance state. Load line and the current in the low impedance state depend on external circuit. Analogous device 100 behavior occurs when the disordered material 160 has threshold voltage Vth2. In this case the device 100 has high impedance state up to voltage 470 and switches to the low impedance state 440. The switching event occurs almost instantaneously and is depicted by the load line 480 in FIG. 4 from the threshold current I@Vth2 to some value of current in the low impedance state.

The particular slopes of the high impedance states 450 and 460 and low impedance state 440 shown in FIG. 4 are illustrative. Actual slopes will depend on the chemical composition and thickness of the material 160. The slopes of lines 420 and 480 of the I-V curves depend on parameters such as the resistance, capacitance etc. of surrounding circuit elements.

It is obvious from FIG. 4 that the disordered material 160 has negative differential resistance part of it I-V characteristics, for example S-type of I-V characteristics for some embodiments and N-type for other embodiments.

FIG. 5 demonstrates a reading of threshold voltages in the invented device 100 programmed into two different high impedance states. The upper curve corresponds to Vth2 and the lower curve corresponds to Vth1 in FIG. 4. The values Vth1 and Vth2 can be read several times in invented device 100 without alteration of the threshold switching voltage value if reading current is clamped by external circuit to a small value, for example 160 microamperes.

In other embodiments a value of device's voltage of is detected, for example the device 100 threshold voltage is read.

In one embodiment the desired Vth value of the device 100 is refreshing after several cycles of reading.

In other embodiments a value of device's impedance of is detected, for example the device 100 resistance is read.

An example of assembly of invented devices 100 into IC is shown in FIG. 6. In particular FIG. 6 shows an exemplary cross-point array 600 in a perspective view that consists of the invented devices 100. In the simplest embodiment the crossbar array can be fabricated with just two masks: word-line mask 610 and bit-line mask 620, with the disordered material 160 sandwiched in between. Word-line 610 plays a role of the electrode 120 in the device 100 in some embodiments. Bit-line 160 plays a role of the electrode 140 in the device 100 in some embodiments.

It has been shown that two electrode devices like one shown in FIG. 1 can be arranged in most cost effective cross-point architecture shown in FIG. 6 tolerant to soft and hard errors of devices, although other architectures, e.g., or multiplexer are also suitable {1A]. Other arrangements in two and three dimensional arrays will of course occur to those skilled in the art.

In the following two sections I describe usage of the invented device 100 for passive configurable, logic and memory applications. IC chip with plurality of electrically connected devices 100 for performing passive and/or active functions can be produced by standard semiconductor technology known to those skilled in the art.

### Passive and Reconfigurable Functions

It is obvious from FIG. 4 that the invented device 100 has different resistances in different polyamorphous states of the disordered material 160. Experiments show that the invented device 100 has different capacitances in different polyamorphous states of the disordered material 160. Moreover, the values of the device 100 properties change upon a transition of the disordered material 160 between different polyamorphous states that correspond to various wells (e.g., 80, 30 and 17) shown in FIG. 2. Therefore the device 100 can serve passive and reconfigurable functions in an integrated circuit (IC).

### Logic Functions

It is obvious from FIG. 4 that the invented device 100 has hysteretic resistor or latch characteristics desirable for logic applications of electronic devices [1]. Because in identical devices 100 Vth value can be tuned in different levels as shown in FIG. 3, combination of these devices can be used to perform logic functions as described in the references [1A, 1B, 1C].

The usage of devices 100 in logic applications is based on the alteration of electrical property (e.g., impedance) performed during change of disorder material 160 from high impedance state to low impedance state or change from low impedance state to high impedance state during the threshold switching of the disorder material 160 under application of external electrical signal, e.g. voltage pulse.

Usage of identical programmable devices 100 simplifies logic IC production and reduces its cost.

### Memory Functions

The device 100 can be used as a memory cell. I describe single bit per memory cell storage for the sake of simplicity although big difference of electrical parameters in various states of the disordered material 160 allows use of the devices 100 for multi-bit per cell information storage (so called, MLC).

The device 100 for memory applications is used when an alteration of an electrical property performed during recording of information in the disorder material 160 and detection of value of this electrical property (or comparison of this electrical property value with a predetermined value) is performed during reading of information.

In a preferred embodiment material 160 is programmed to different values of threshold switching voltage (for example Vth1 and Vth2) and is used to code information in binary form in a device 100. Let assume that logical 0 corresponds to Vth1 value and logical 1 corresponds to Vth2 value. Read voltage Vread (that satisfies conditions Vread>Vth1 and Vread<Vth2) is applied between electrodes 120 and 140 and clumped current through device 100 is compared with demarcation value Ir that exceeds the maximum threshold current. In other words Ir satisfies the condition Ir>max(I@Vth1, I@Vth2). The device 100 storages logical 1 if the current through device 100 is smaller than Ir, and the device 100 storages logical 0 if the current through device 100 is higher than Ir. Such read is fast and does not destroy information stored in device 100 (see FIG. 5). In some embodiments the device 100 state 0 or 1 can be refreshed after several read cycles. Because polyamorphous states with Vth1 and Vth2 are metastable, the memory based on them is non-volatile. Because transition between various polyamorphous states appears without change in atomic long-range order, the recording of information is quite fast (below 450 picoseconds). Therefore the device 100 is suitable as DRAM or SRAM.

In another embodiment the different values of high impedance and low impedance of device 100 are used to code information in binary form during device 100 programming. In this case the device 100 is functioning as a resistive (for example, phase-change) memory and suitable as FLASH memory.

In another embodiment the different values of high impedances of device 100 are used to code information in binary or another form for single bit per cell or multiple bits per cell information storage during device 100 programming.

Usage of devices 100 in different high impedance states allows avoid selector devices for each cell of memory array in some embodiments shown in FIG. 6. Selector-free memory array has high density and small cost.

It is worth to note that the programming and reading of invented device 100 and arrays from such devices are generally similar to well known programming and reading of different types of resistive memories [3-7]. Hence usage of the devices 100 as memory cells does not require significant changes in design of memory chip periphery circuits such as controllers, comparators, etc.

Because devices 100 are not use silicon wafer real estate they can be produced between the top metallization levels in three dimensional architecture of memory or logic IC.

### Legal Boundaries of Invention

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of portions and/or steps and/or segments may be exaggerated for clarity.

It will be understood that, although the terms first, second, third etc. may be used herein to describe various portions and/or steps and/or segments, these portions and/or steps and/or segments should not be limited by these terms. These terms are only used to distinguish one portion and/or step and/or segment from another portion and/or step and/or segment. Thus, a first portion and/or step and/or segment discussed below could be termed a second portion and/or step and/or segment without departing from the teachings of the present invention.

Temporary relative terms, such as “after,” and “before” and the like, may be used herein for ease of description to describe one portions and/or steps and/or segments or feature's relationship to another portions and/or steps and/or segments(s) or feature(s) as illustrated in the figures.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated portions and/or steps and/or segments and/or features, but do not preclude the presence or addition of one or more other portions and/or steps and/or segments, and/or features thereof.

Example embodiments of the present invention are described herein with reference to drawings that are schematic illustrations of idealized embodiments of the present invention. As such, variations from the shapes of the illustrations as a result, for example, of a noise or a signal's attenuation in circuits and memory array, are to be expected. Thus, example embodiments of the present invention should not be construed as limited to the particular shapes of regions illustrated herein but are to include deviations in shapes that result, for example, from signals processing. Thus, the portions illustrated in the figures are schematic in nature and their shapes are not intended to illustrate the actual shape of a signal portion and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein in connection with the description of the invention, the term “about” means+/−10%. By way of example, the phrase “about 160” indicates a range of between 90 and 620. With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form portions and/or steps and/or segments of the invention are useful operations. The invention also relates to a device or an apparatus for performing these operations. The apparatus may be specially constructed for the required purposes, or it may be a general-purpose apparatus. In particular, various general-purpose or apparatus may be used with computer programs written in accordance with the teachings herein, or it may be more convenient to construct a more specialized apparatus to perform the required operations.

It will be further appreciated that the instructions represented by the operations in the above figures are not required to be performed in the order illustrated, and that all the processing represented by the operations may not be necessary to practice the invention. Further, the processes described in any of the above figures can also be implemented in the specially constructed or/and general-purpose apparatus.

Although the foregoing invention has been described in some detail for purposes of clarity of understanding, it will be apparent that certain changes and modifications may be practiced within the scope of the appended claims.

Accordingly, the present embodiments are to be considered as illustrative and not restrictive, and the invention is not to be limited to the details given herein, but may be modified within the scope and equivalents of the appended claims.

While the above description contains specificities, these should not be construed as limitations on the scope of any embodiment, but as exemplifications of the presently preferred embodiments thereof. Many other ramifications and variations are possible within the teachings of the various embodiments. Thus the scope of the invention should be determined by the appended claims and their legal equivalents, and not by the examples given.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

Although a preferred embodiment of the present invention has been described for illustrative purposes, those skilled in the art will appreciate that various modifications, additions and substitutions are possible, without departing from the scope and spirit of the invention as disclosed in the accompanying main claims.

The present invention may be embodied in other specific forms without departing from the spirit or essential attributes thereof and, accordingly, reference should be made to the appended claims and any of their permutation or any attempt to go into their details rather than to the foregoing specification, as indicating the scope of the invention.

### REFERENCES

[1A] G. Snider, “Computing with hysteretic resistor crossbars”, Applied Physics A: Materials Science and Processing, Volume 80, Issue 6, Pages 1165-1172 (2005).
[1B] G. Snider, “Architecture and methods for computing with reconfigurable resistor crossbars” U.S. Pat. No. 7,203,789.
[1C]. S. R. Ovshinsky “Logical operation circuit employing two-terminal chalcogenide switches” U.S. Pat. No. 5,543,737.
[2A] Y. C. Chen, et. al. Lu, “An Access-Transistor-Free (0T/1R) Non-Volatile Resistance Random Access Memory (RRAM) Using a Novel Threshold Switching, Self-Rectifying Chalcogenide Device”—Electron Devices Meeting, 2003. IEDM '03 Technical Digest, p. 37.4.1-37.4.4; U.S. Pat. Nos. 7,180,767, 7,236,394, 7,272,037; US patent applications 2007/0247899
[2B] G. A. Gordon, et. al. “Programming a normally single phase chalcogenide material for use as a memory or FPLA” US patent application 2004/0257848, 2005/0041467.
[3] Daniele Ielmini and Yuegang Zhang, “Physics-based analytical model of chalcogenide-based memories for array simulation”—Electron Devices Meeting, 2006. IEDM '06. International 11-13 Dec. 2006 Page(s):1-4 DOI 10.1109/IEDM.2006.346795
[4] J. C. Scott, L. D. Bozano “Nonvolatile Memory Elements Based on Organic Materials”, Advanced Materials Volume 19, Issue 11, Pages 1452-1463 May 2007
[5] Alex Ignatiev, Naijuan Wu, Xin Chen, Yibo Nian, Christina Papagianni, Shangqing Liu, John Strozier, “Resistance Non-volatile Memory: RRAM” MRS 2007 xSpring
[6] M. N. Kozicki, M. Park, M. Mitkova, “Nanoscale Memory Elements Based on Solid-State Electrolytes”, IEEE Trans. On Nanotechnology 4 No 3 (2005) p. 331
[7] R. Waser, Masakazu Aono “Nanoionics-based resistive switching memories”, Nature Materials, Volume 6, Issue 11, Pages 833-840 (2007).
[8A] Loerting T., Giovambattista N. “Amorphous ices: Experiments and numerical simulations” Journal of Physics Condensed Matter v 18, pages R919-R977 (2006)
[8B] Henderson G. S. “The structure of silicate melts: A glass perspective” Canadian Mineralogist, Vol. 43, N 6, p. 1921-1958 (2005)
[8C] Sen S., Gaudio S., Aitken B. G., Lesher C. E. “Observation of a pressure-induced first-order polyamorphic transition in a chalcogenide glass at ambient temperature” Physical Review Letters, v. 97, N2, p. 25504/1-4 (2006, July 14)
[8D] A. S. Bakai, “On low-temperature polyamorphous transformations”, Fizika Nizkikh Temperatur: Volume 32, Number 8-9, p. 1143-1154 (August 2006),
[8E] Wilding M. C., Wilson M., McMillan P. F. “Structural studies and polymorphism in amorphous solids and liquids at high pressure”, Chemical Society Reviews, vol. 35, N10, p. 964-986 (2006).
[8F] Sheng H. W., Liu H. Z., Cheng Y. Q., Wen J., Lee P. L., Luo W. K., Shastri S. D., Ma E. “Polyamorphism in a metallic glass”, Nature Materials, v. 6, N3, p. 192-197 (2007)
[9A]. W. Van Rosebroeck and H. C. Casey Jr., “Transport in relaxation semiconductors,” Phys. Rev. B, vol. 5, no. 6, p. 2154, 1972; U.S. Pat. No. 3,697,834
[9B]. B. T. Cavicchi and N. M. Haegel, “Experimental evidence of relaxation phenomenon in high purity silicon,” Phys. Rev. Lett., vol. 63, p. 195, 1989.
[9C]. N. M. Haegel, “Relaxation Semiconductors: In theory and in practice,” Phys. A, vol. 53, p. 1, 1991.
[9D]. N. Derhacobian, N. M. Haegel, “Experimental study of transport in a trap-dominated relaxation semiconductor”, Physical Review B, Vol. 44, N. 23, December 1991.

1. Device comprising a disordered material that has at least two high impedance states and at least one low impedance state, and two or more electrodes in electrical contact with said material.

2. The device of claim 1, wherein said two or more high impedance states of said disorder material correspond to different polyamorphous atomic configurations.

3. The device of claim 1, wherein said disorder material in a high impedance state has a dielectric relaxation time longer than a carrier diffusion lifetime by a factor of at least two.

4. The material of claim 2, being in said two or more polyamorphous atomic configurations has the dielectric relaxation time longer than carrier diffusion lifetime of charge carriers by a factor of at least two.

5. The material of claim 3, has said two or more polyamorphous atomic configurations.

6. The device of claim 1, wherein electrical property of said disordered material can be altered or detected upon application of an electrical signal between said first and second electrically conductive electrodes, wherein said electrical signal compromises a rectangular pulse, or a triangular pulse, or free-shape pulse, or group of pulses with uniform or non-uniform amplitudes and/or durations, or constant bias.

7. At least one of the devices described in claim 1 embedded in an integrated circuit for performing at least one of functions compromising passive resistor, passive capacitor, reconfigurable resistor, reconfigurable capacitor, binary logic element, non-binary logic element, volatile memory, non-volatile memory.

8. The device of claim 1, wherein said disordered material has negative differential resistance part of it I-V characteristics compromising S-type or N-type characteristics.

9. The device of claim 1, wherein said disordered material can be programmed to have different electrical properties compromising resistance, capacitance, impedance, threshold switching voltage, threshold switching current.

10. The device of claim 1 in said high impedance states, wherein said disordered material has resistance above 10 MOhm.

11. The device of claim 1 in said low impedance states, wherein said disordered material has resistance below 30 kOhm.

12. The device of claim 1, wherein said disordered material is organic and compromises at least one carbon-hydrogen (C—H) bond or at least one carbon-oxygen (C—O) bonds.

13. The device of claim 1, wherein said inorganic disordered material compromises of at least one of oxides WO3 or PbO or V2O5 or CuO or Fe2O3 or Ag2O or MgO or CaO or SrO or BaO or CdO or ZnO or CeO2 or Pr2O3 or Nd2O3 or TeO or Sb2O3 or TiO2.

14. The device of claim 1, wherein said inorganic disordered material compromises a chalcogen group element (tellurium Te or selenium Se or sulfur S or oxygen O), or a nitrogen group element (nitrogen N or phosphorus P or arsenic As or antimony Sb or bismuth Bi), or boron group element (boron B or aluminum Al or gallium Ga or indium In or thallium Tl), or a metalloid element ((silicon Si or germanium Ge or carbon C), or their binary or ternary or more complicated combination.

15. The device of claim 1, wherein said disordered material does not have p-n junction inside or with said electrodes.

16. The device of claim 1, wherein said the interaction between said charge carriers and excitations of said polyamorphous atomic configuration in said disordered material leads to self-trapping of the charge carriers.

17. The device of claim 1, wherein −U centers with negative Hubbard correlation energy exist in said material.

18. The device of claim 1, wherein said −U centers pin the Fermi level near middle of the forbidden gap of said material.

19. The device of claim 1, wherein said distance between said electrodes is between 1 nm and 1 m.

20. An integrated circle includes a plurality of electrically connected said devices according to the claim 1 for performing a function compromising passive or reconfigurable or logic or memory functions or combination of these function.
